(19) United States
(12) Patent Application Publication
(10) Pub. No.: US 2024/0304504 A1
(43) Pub. Date: Sep. 12, 2024

(54) SEMICONDUCTOR PACKAGE INCLUDING A TEST BUMP

(71) Applicant: SAMSUNG ELECTRONICS CO., LTD., SUWON-SI (KR)

(72) Inventors: Boin NOH, Suwon-si (KR); Yongho KIM, Suwon-si (KR); Sunoo KIM, Suwon-si (KR)

(21) Appl. No.: 18/598,077

(22) Filed: Mar. 7, 2024

(30) Foreign Application Priority Data
Mar. 8, 2023 (KR) 10-2023-0030813

(51) Int. Cl. H01L 21/66; H01L 23/00; H01L 23/498; H01L 25/065

(52) U.S. Cl. CPC H01L 22/32; H01L 23/49816; H01L 24/08; H01L 24/16; H01L 25/0652; H01L 2224/08146; H01L 2224/08155; H01L 2224/16146; H01L 2224/16157; H01L 2924/01029; H01L 2924/0665; H01L 2924/1431; H01L 2924/1434; H01L 2924/15311

(57) ABSTRACT

A semiconductor package includes: a semiconductor chip including an active layer; a bump pad positioned on the active layer; a passivation layer covering the bump pad and including a first opening and a second opening, wherein the first opening exposes a first portion of the second surface of the bump pad, and the second opening exposes a second portion of the second surface of the bump pad; a first bump disposed on the first portion of the second surface of the bump pad, which is exposed through the first opening; and a test bump disposed on the second portion of the second surface of the bump pad, which is exposed through the second opening, wherein the first bump includes at least one metal layer, and a length of the test bump in a vertical direction is less than a length of the first bump in the vertical direction.

### CROSS-REFERENCE TO RELATED APPLICATION

This application claims priority under 35 U.S.C. § 119 to Korean Patent Application No. 10-2023-0030813, filed on Mar. 8, 2023, in the Korean Intellectual Property Office, the disclosure of which is incorporated by reference herein in its entirety.

### TECHNICAL FIELD

Embodiments of the present inventive concept relate to a semiconductor package, and more particularly, to a semiconductor package including a test bump.

### DISCUSSION OF THE RELATED ART

As the storage capacity of semiconductor devices has increased, semiconductor packages including semiconductor devices are desired to be thinner and lighter. Recently, studies on increasing the operating speed of a plurality of semiconductor chips and studies on increasing structural reliability of semiconductor packages have been actively conducted.

### SUMMARY

According to an embodiment of the present inventive concept, a semiconductor package includes: a semiconductor chip including an active layer; a bump pad positioned on the active layer and including a first surface and a second surface, wherein the first surface is disposed on the active layer, and the second surface is opposite to the first surface; a passivation layer covering the bump pad and including a first opening and a second opening, wherein the first opening exposes a first portion of the second surface of the bump pad, and the second opening exposes a second portion of the second surface of the bump pad; a first bump disposed on the first portion of the second surface of the bump pad, which is exposed through the first opening; and a test bump disposed on the second portion of the second surface of the bump pad, which is exposed through the second opening, wherein the first bump includes at least one metal layer, and a length of the test bump in a vertical direction is less than a length of the first bump in the vertical direction.

According to an embodiment of the present inventive concept, a semiconductor package includes: a semiconductor chip including an active layer; a bump pad positioned on the active layer and including a first surface and a second surface, wherein the first surface is disposed on the active layer, and the second surface is opposite to the first surface; a passivation layer covering the bump pad and including a first opening and a second opening, wherein the first opening exposes a first portion of the second surface of the bump pad, and the second opening exposes a second portion of the second surface of the bump pad; a first bump disposed on the first portion of the second surface of the bump pad, which is exposed through the first opening; a test bump disposed on the second portion of the second surface of the bump pad, which is exposed through the second opening; an underfill material layer at least partially surrounding the first bump and the test bump; and lower silicon on which a pad, which is electrically connected to the first bump, is formed, wherein a length of the first bump in a first horizontal direction is in a range of about 5 μm to about 30 μm, wherein a length of the first bump in a vertical direction is in a range of about 5 μm to about 50 μm, wherein the first bump includes at least one metal layer, and a length of the test bump in the vertical direction is less than a length of the first bump in the vertical direction.

According to an embodiment of the present inventive concept, a semiconductor package includes: a semiconductor chip including an active layer; a bump pad positioned on the active layer and including a first surface and a second surface, wherein the first surface is in contact with the active layer, and the second surface is opposite to the first surface; a passivation layer disposed on the bump pad and including a first opening and a second opening, wherein the first opening exposes a first portion of the second surface of the bump pad, and the second opening exposes a second portion of the second surface of the bump pad; a first bump disposed on the first portion of the second surface of the bump pad, which is exposed through the first opening, wherein the first bump includes a metal layer and a solder, wherein the metal layer includes at least one layer; a test bump disposed on the second portion of the second surface of the bump pad, which is exposed through the second opening, wherein the test bump includes a test metal layer and a solder; an underfill material layer at least partially surrounding the first bump and the test bump; a seed metal layer formed in each of the first opening and the second opening; and lower silicon on which a pad, which is electrically connected to the first bump, is formed, wherein each of a surface of the first bump and a surface of the test bump is curved, wherein a length of the first bump in a first horizontal direction is in a range of about 5 μm to about 30 μm, and a length of the first bump in a vertical direction is in a range of about 5 μm to about 50 μm, wherein a length of the test bump in a vertical direction is less than a length of the first bump in the vertical direction, wherein the metal layer of the first bump includes at least one of copper or nickel, and wherein a cross-sectional area of the test bump in a horizontal direction is greater than a cross-sectional area of the first bump in the horizontal direction.

### BRIEF DESCRIPTION OF THE DRAWINGS

The above and other aspects of the present inventive concept will become more apparent by describing in detail embodiments thereof, with reference to the accompanying drawings, in which:

FIG. 1A is a cross-sectional view of a semiconductor package according to an embodiment of the present inventive concept;

FIG. 1B is a schematic cross-sectional view of a first chip structure of FIG. 1A;

FIG. 1C is a cross-sectional view of a semiconductor package according to an embodiment of the present inventive concept;

FIG. 2 is a schematic diagram illustrating portions AA to CC respectively shown in FIGS. 1A to 1C;

FIG. 3 is a cross-sectional view illustrating a first bump and a test bump of FIG. 2;

FIG. 4 is a plan view illustrating a first bump and a test bump of FIG. 2;

FIG. 5A is a cross sectional of a semiconductor package according to an embodiment of the present inventive concept;

FIG. 5B is a cross-sectional view of a semiconductor package according to an embodiment of the present inventive concept;

FIG. 5C is a cross-sectional view of a semiconductor package according to an embodiment of the present inventive concept; and

FIG. 5D is a cross-sectional view of a semiconductor package according to an embodiment of the present inventive concept.

### DETAILED DESCRIPTION OF THE EMBODIMENTS

Hereinafter, embodiments of the present inventive concept will be described in detail with reference to the accompanying drawings. Like components are denoted by like reference numerals throughout the specification and the drawings, and thus, repeated descriptions thereof may be omitted or briefly discussed.

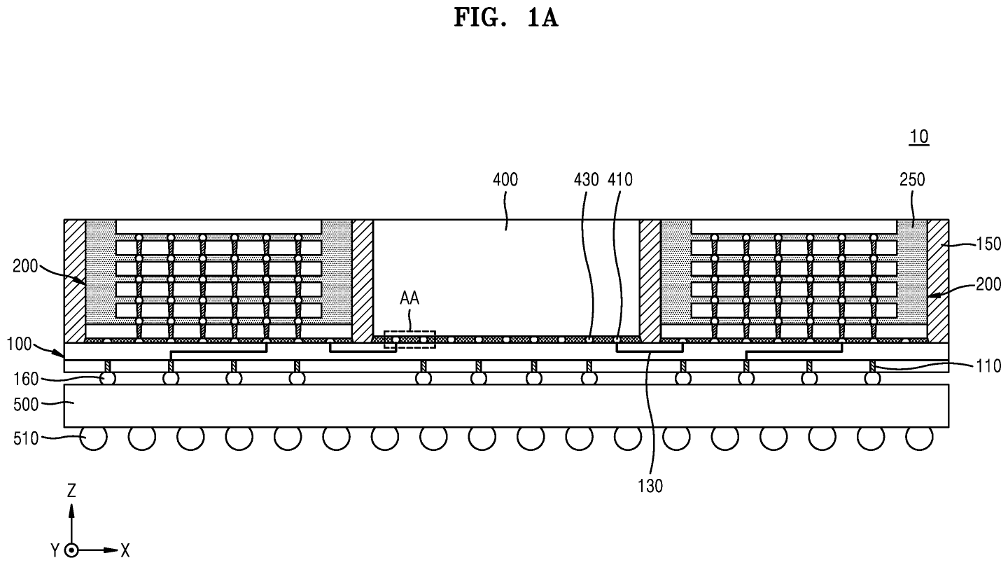

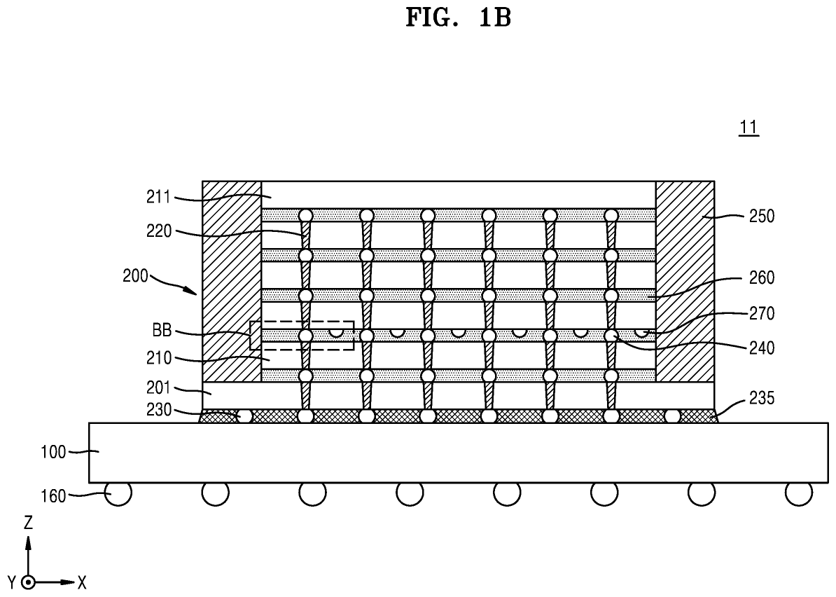

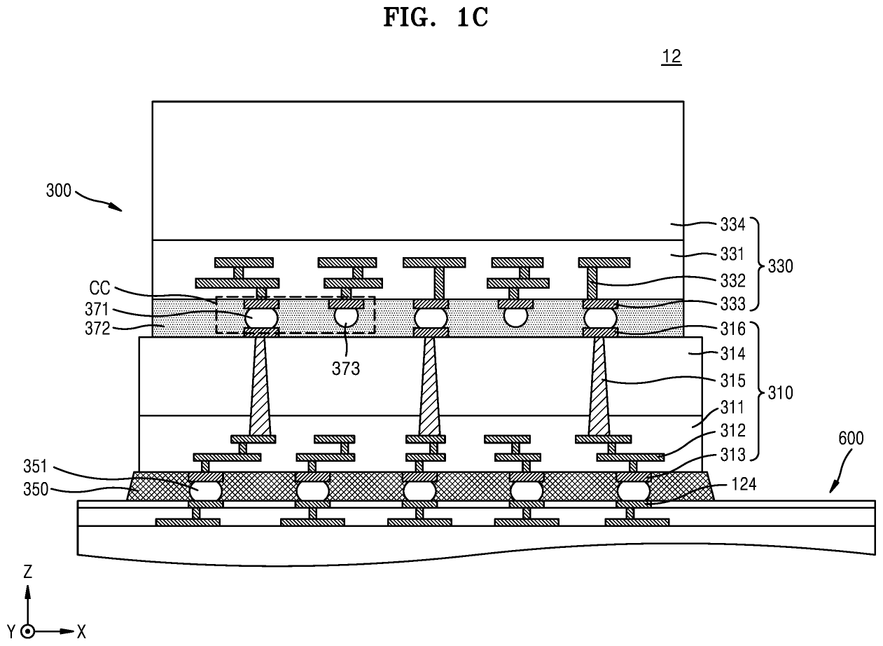

FIG. 1A is a cross-sectional view of a semiconductor package 10 according to an embodiment of the present inventive concept.

Referring to FIG. 1A, the semiconductor package 10 may include a first substrate 100, a first external connection terminal 160, a package substrate 500, a second external connection terminal 510, a first chip structure 200, and a second chip structure 400.

According to some embodiments of the present inventive concept, the first substrate 100 may be arranged on the package substrate 500. The first substrate 100 may be electrically connected to the package substrate 500 through the first external connection terminal 160. The first external connection terminal 160 may physically and electrically connect the first substrate 100 and the package substrate 500 to each other. The first external connection terminal 160 may include at least one conductive material, for example, solder, tin (Sn), silver (Ag), copper (Cu), and aluminum (Al).

Hereinafter, in the drawings, an X-axis direction and a Y-axis direction may indicate directions parallel to an upper or lower surface of the first substrate 100, and the X-axis direction and the Y-axis direction may be directions substantially perpendicular to each other. A Z-axis direction may indicate a direction substantially perpendicular to the upper or lower surface of the first substrate 100. In other words, the Z-axis direction may be a direction substantially perpendicular to an X-Y plane. In addition, hereinafter, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

According to some embodiments of the present inventive concept, the first substrate 100 may include an interposer substrate. The first chip structure 200 and the second chip structure 400 may be electrically connected to each other through the first substrate 100, and the first chip structure 200 and the second chip structure 400 may each be electrically connected to the package substrate 500 through the first substrate 100. According to some embodiments of the present inventive concept, the first substrate 100 may be a silicon (Si) interposer substrate having a 2.5D package structure. For example, the semiconductor package 10 may be understood as a 2.5D package having a structure in which different kinds of semiconductor chips may be electrically connected to each other through an interposer substrate.

The first substrate 100 may include a base layer and a redistribution structure arranged on the base layer. The first substrate 100 may electrically connect the first chip structure 200 and the second chip structure 400 to each other through a redistribution pattern 130 that is formed in the redistribution structure. A through electrode 110 may be formed in the base layer, and the through electrode 110 may be electrically connected to the redistribution pattern 130 of the of the redistribution structure. Accordingly, the first substrate 100 may electrically connect the first chip structure 200 and the second chip structure 400 to the package substrate 500 through the through electrode 110 that is formed in the base layer of the first substrate 100.

The package substrate 500 is a support substrate on which the first substrate 100 is mounted, and may include at least one layer of wires therein. In a case where the wires are formed of a multilayer, wires of different layers may be connected to each other through a via. In some embodiments of the present inventive concept, the package substrate 500 may include through electrodes connecting pads on the upper and lower surfaces thereof to each other. A protective layer, such as solder resist, may be formed on the upper and lower surfaces of the package substrate 500. Substrate pads of the package substrate 500 may be connected to wires of a wiring layer and may be exposed from the protective layer. For example, the substrate pads might not be covered by the protective layer.

The second external connection terminal 510 may be positioned on the lower surface of the package substrate 500. The second external connection terminal 510 may be electrically connected to external devices, for example, a motherboard. The second external connection terminal 510 may be electrically connected to the package substrate 500. The second external connection terminal 510 may be electrically connected to wire patterns in the package substrate 500 through a substrate pad that is attached to the lower surface of the package substrate 500. The second external connection terminal 510 may electrically and physically connect the semiconductor package 10 and an external device, on which the semiconductor package 10 is mounted, to each other.

The first chip structure 200 may include at least one semiconductor chip. For example, the semiconductor chip may include a logic semiconductor chip or a memory semiconductor chip. The logic semiconductor chip may be, for example, a microprocessor, such as a central processing unit (CPU), a graphics processing unit (GPU), or an application processor (AP), an analog device, or a digital signal processor. The memory semiconductor chip may include, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM).

According to some embodiments of the present inventive concept, the first chip structure 200 may include a plurality of semiconductor chips stacked on each other. The plurality of semiconductor chips may be sealed by a first molding member 250. The first chip structure 200 including the plurality of semiconductor chips is described in detail with reference to FIG. 1B.

The second chip structure 400 may be arranged on an upper surface of the first substrate 100. According to some embodiments of the present inventive concept, the second chip structure 400 is an application-specific integrated circuit (ASIC) package including a logic chip, and may be positioned at a central portion of the upper surface of the first substrate 100.

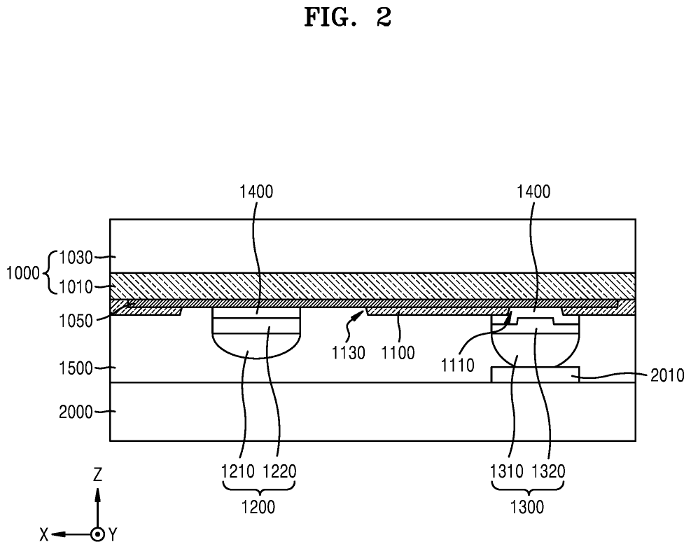

According to some embodiments of the present inventive concept, the second chip structure 400 may be mounted on the first substrate 100 in a flip chip method through a first bump 410, such as a micro bump. A test bump 430 may be formed adjacent to the first bump 410. The first bump 410 and the test bump 430 are described in detail below with reference to FIG. 2 and subsequent drawings. As described below, the first bump 410 may be understood as a first bump 1300 of FIG. 2, and the test bump 430 may be understood as a test bump 1200 of FIG. 2. This may indicate that the first bump 410 and the test bump 430 of the semiconductor package 10 are included, since an embodiment of the present inventive concept includes the first bump 1300 and the test bump 1200 of FIG. 2.

The first chip structure 200 and the second chip structure 400 may be mounted on the first substrate 100 and may be arranged on the first substrate 100 in a first horizontal direction X. For example, the first chip structure 200 and the second chip structure 400 may be arranged on the first substrate 100 and may be spaced apart from each other in the first horizontal direction X.

A second molding member 150 may at least partially surround the first chip structure 200 and the second chip structure 400 and may be disposed on the first substrate 100. The second molding member 150 may cover the upper surface of the first substrate 100, and may cover sidewalls of each of the first chip structure 200 and the second chip structure 400. In some embodiments of the present inventive concept, the second molding member 150 covers the sidewalls of the first chip structure 200 and the second chip structure 400, but might not cover upper surfaces of the first chip structure 200 and the second chip structure 400. The second molding member 150 may include, for example, an epoxy resin and an inorganic filler and/or an organic filler included in the epoxy resin. In some embodiments of the present inventive concept, the second molding member 150 may include an epoxy mold compound (EMC).

According to some embodiments of the present inventive concept, the upper surfaces of the first chip structure 200 and the second chip structure 400 may be at substantially the same level in a vertical direction Z. For example, the upper surfaces of the first chip structure 200 and the second chip structure 400 may be positioned at substantially the same height as one another. According to some embodiments of the present inventive concept, the upper surface of the second molding member 150 may be on the same plane as that of the upper surfaces of the first chip structure 200 and the second chip structure 400.

FIG. 1B is a schematic cross-sectional view of the first chip structure 200 of FIG. 1A.

Referring to FIG. 1B, a semiconductor package 11 may include the first substrate 100, the first external connection terminal 160, the first chip structure 200, and the first molding member 250. Because the first substrate 100 and the first external connection terminal 160 are substantially the same as or similar to the first substrate 100 and the first external connection terminal 160 of FIG. 1A, redundant descriptions thereof are omitted.

According to some embodiments of the present inventive concept, the first chip structure 200 may include a plurality of semiconductor chips stacked in a vertical direction. According to some embodiments of the present inventive concept, the plurality of semiconductor chips are high bandwidth memory (HBM) DRAM chips, and may be semiconductor chips used in an HBM package. According to some embodiments of the present inventive concept, the first chip structure 200 may include a base chip 201 and a plurality of semiconductor chips 210 that are disposed on the base chip 201, and each of the base chip 201 and the plurality of semiconductor chips 210 may include a through electrode 220 that is disposed in the base chip 201 and the plurality of semiconductor chips 210. A top-layer semiconductor chip 211, which is a semiconductor chip stacked on an uppermost semiconductor chip among the plurality of semiconductor chips 210, might not include the through electrode 220.

According to some embodiments of the present inventive concept, the base chip 201 may include logic devices. Accordingly, the base chip 201 may be a logic chip. The base chip 201 may be arranged below the plurality of semiconductor chips 210 to integrate signals of the plurality of semiconductor chips 210 and transfer the integrated signal to the outside, and also transfer signals and power from the outside to the plurality of semiconductor chips 210. Accordingly, as an example, the base chip 201 may be referred to as a buffer chip or a control chip. The plurality of semiconductor chips 210 may include a plurality of memory devices, for example DRAM devices. The plurality of semiconductor chips 210 may be referred to as memory chips or core chips.

The plurality of semiconductor chips 210 may be stacked on the base chip 201 through pad-to-pad bonding, bonding using a bonding member, or bonding using an anisotropic conductive film (ACF). According to some embodiments of the present inventive concept, the plurality of semiconductor chips 210 may be mounted on the base chip 201 through a first bump 240 or on a semiconductor chip 210 that is positioned directly there below in a flip chip method. According to some embodiments of the present inventive concept, the first bump 240 may include a micro bump.

A test bump 270 may be formed adjacent to the first bump 240. The first bump 240 and the test bump 270 are described in detail below with reference to FIG. 2 and subsequent drawings. At this time, as described below, the first bump 240 may correspond to the first bump 1300 of FIG. 2, and the test bump 270 may correspond to the test bump 1200 of FIG. 2. This may indicate that the first bump 240 and the test bump 270 of the semiconductor package 11 of FIG. 1B are included, since an embodiment of the present inventive concept includes the first bump 1300 and the test bump 1200 of FIG. 2.

According to some embodiments of the present inventive concept, an underfill material layer 260 at least partially surrounding the first bump 240 may be arranged between the base chip 201 and the semiconductor chip 210 and between the plurality of semiconductor chips 210. The underfill material layer 260 may be formed of, for example, an epoxy resin formed by a capillary under-fill method. However, in some embodiments of the present inventive concept, the first molding member 250 may fill a gap between the base chip 201 and the semiconductor chip 210 or between the plurality of semiconductor chips 210 through a molded underfill process. In this case, the underfill material layer 260 may be omitted.

A first bump structure 230 arranged on a lower surface of the base chip 201 may be electrically connected to the through electrode 220 formed in the base chip 201. According to some embodiments of the present inventive concept, because the first bump structure 230 is substantially the same as or similar to the first bump 410 (see FIG. 1A) described with reference to FIG. 1A, a detailed description thereof is omitted.

The through electrode 220 formed in each of the plurality of semiconductor chips 210 may be electrically connected to the first bump 240. The through electrode 220 may penetrate the base chip 201 and each of the plurality of semiconductor chips 210. The through electrode 220 may extend in the vertical direction Z. In FIG. 1B, the through electrode 220 is shown in a shape in which a width thereof decreases as a level in the vertical direction Z decreases, but the present inventive concept is not limited thereto, and the width of the through electrode 220 in a horizontal direction may decrease or increase as the level in the vertical direction Z increases. For example, the through electrode 220 may have a tapered shape in which a horizontal width thereof varies according to a level in the vertical direction Z. For example, the through electrode 220 may have a tapered shape or an inverted tapered shape. As another example, the through electrode 220 may have a constant width. At least a portion of the through electrode 220 may have a pillar shape or a cylindrical shape. The through electrode 220 may include a through silicon via (TSV).

The first chip structure 200 may further include the first molding member 250 at least partially surrounding the base chip 201 and the plurality of semiconductor chips 210. The plurality of semiconductor chips 210 on the base chip 201 may be sealed by the first molding member 250. However, in some embodiments of the present inventive concept, a top-layer semiconductor chip 211 stacked on an uppermost semiconductor chip among the plurality of semiconductor chips 210 might not be covered by the first molding member 250. However, in some embodiments of the present inventive concept, the top-layer semiconductor chip 211 may also be covered by the first molding member 250.

According to some embodiments of the present inventive concept, the first molding member 250 may be formed of a thermosetting resin such as epoxy resin, a thermoplastic resin such as polyimide, or a resin including a reinforcing material such as an inorganic filler in the thermosetting resin or the thermoplastic resin, in particular, an Ajinomoto build-up film (ABF), FR-4, BT, or the like, but the present inventive concept is not limited thereto, and the first molding member 250 may be formed of a molding material such as EMC or a photosensitive material such as photoimagable encapsulant (PIE). In some embodiments of the present inventive concept, a portion of the first molding member 250 may include an insulating material, such as a silicon oxide film, a silicon nitride film, or a silicon oxynitride film.

FIG. 1C is a cross-sectional view of a semiconductor package 12 according to an embodiment of the present inventive concept.

Referring to FIG. 1C, the semiconductor package 12 may include a substrate 600, an upper semiconductor chip 330, and a lower semiconductor chip 310.

The substrate 600 may include layers mutually stacked in the vertical direction Z. The substrate 600 may include upper and lower surfaces opposite to each other, and at least one of the upper and lower surfaces may be substantially flat. The substrate 600 may be a package substrate on which a third chip structure 300 is mounted. In some embodiments of the present inventive concept, the substrate 600 may be a redistribution substrate manufactured through a redistribution process. In some embodiments of the present inventive concept, the substrate 600 may include a printed circuit board (PCB).

The third chip structure 300 may include the upper semiconductor chip 330, the lower semiconductor chip 310, a first bump 371, and an underfill material layer 372. The third chip structure 300 may be mounted on the upper surface of the substrate 600.

The lower semiconductor chip 310 may be arranged on the upper surface of the substrate 600. The upper semiconductor chip 330 may be stacked on the lower semiconductor chip 310. For example, the upper semiconductor chip 330 may be arranged on an upper surface of the lower semiconductor chip 310.

Each of the lower semiconductor chip 310 and the upper semiconductor chip 330 may be a logic chip or a memory chip. For example, both the lower semiconductor chip 310 and the upper semiconductor chip 330 may be memory chips of the same type, or one of the lower semiconductor chip 310 or the upper semiconductor chip 330 may be a memory chip, and the other one may be a logic chip.

The memory chip may include, for example, a volatile memory chip, such as DRAM or SRAM, or a non-volatile memory chip, such as PRAM, MRAM, FeRAM, or RRAM. The logic chip may be, for example, a microprocessor, such as a CPU, a GPU, or an AP, an analog device, or a digital signal processor.

The lower semiconductor chip 310 may include a first semiconductor substrate 314, a first device layer 311, a first bump pad 313, and a second bump pad 316.

The first semiconductor substrate 314 may have an upper surface and a lower surface, which are opposite to each other. The upper surface may be a surface facing the upper semiconductor chip 330, and the lower surface may be a surface facing the substrate 600. The upper surface may be referred to as an inactive surface, and the lower surface may be referred to as an active surface.

The first semiconductor substrate 314 may include silicon (Si), for example, crystalline silicon, polycrystalline silicon, or amorphous silicon. In addition, the first semiconductor substrate 314 may include a semiconductor element such as germanium (Ge), or a compound semiconductor such as silicon carbide (SiC), gallium arsenide (GaAs), indium arsenide (InAs), and indium phosphide (InP). The first semiconductor substrate 314 may have a silicon-on-insulator (SOI) structure. For example, the first semiconductor substrate 314 may include a buried oxide (BOX) layer. The first semiconductor substrate 314 may include a conductive region, for example, a well doped with impurities, or a structure doped with impurities. In addition, the first semiconductor substrate 314 may have various device isolation structures, such as a shallow trench isolation (STI) structure.

The first device layer 311 may include a first wire pattern 312 electrically connected to a plurality of semiconductor devices that are formed on the first semiconductor substrate 314. The first wire pattern 312 may include a metal wire layer and a via plug. For example, the first wire pattern 312 may have a multi-layered structure where two or more metal wire layers and/or two or more via plugs are alternately stacked.

According to some embodiments of the present inventive concept, the first device layer 311 may be formed on a lower surface of the first semiconductor substrate 314, which is an active surface. The first device layer 311 may be positioned below the first semiconductor substrate 314. The first semiconductor substrate 314 may be spaced apart from the substrate 600 in the vertical direction Z with the first device layer 311 therebetween. The lower semiconductor chip 310 may include a through electrode 315 penetrating at least a portion of the first device layer 311 and the first semiconductor substrate 314.

The first bump pad 313 may be arranged on a lower surface of the first device layer 311 and may be electrically connected to the first wire pattern 312 that is disposed inside the first device layer 311. The first bump pad 313 may be electrically connected to the through electrode 315 through the first wire pattern 312.

The through electrode 315 may penetrate the first semiconductor substrate 314 and at least a portion of the first device layer 311. The through electrode 315 may extend from the first device layer 311 toward an upper surface of the first semiconductor substrate 314 in the vertical direction Z, and may be electrically connected to the first wire pattern 312 that is provided in the first device layer 311. Accordingly, the first bump pad 313 may be electrically connected to the through electrode 315 through the first wire pattern 312. For example, the through electrode 315 may have a tapered shape in which a width thereof in a horizontal direction decreases or increases as a level in the vertical direction Z increases. At least a portion of the through electrode 315 may have a pillar shape or a cylindrical shape. The through electrode 315 may be a TSV.

The second bump pad 316 may be formed on the upper surface of the first semiconductor substrate 314, that is, on an inactive surface of the first semiconductor substrate 314. The second bump pad 316 may include substantially the same material as that of the first bump pad 313. In addition, according to some embodiments of the present inventive concept, a passivation layer may be formed on the upper surface of the first semiconductor substrate 314 and may at least partially surround a portion of side surfaces of the second bump pad 316. The passivation layer is described in detail below with reference to FIG. 2 and subsequent drawings.

An underfill layer 350 may be disposed between the lower semiconductor chip 310 and the substrate 600. The underfill layer 350 may be disposed between the lower semiconductor chip 310 and the substrate 600 while surrounding a second bump structure 351. The underfill layer 350 may include, for example, an epoxy resin formed by a capillary under-fill method. In some embodiments of the present inventive concept, the underfill layer 350 may cover at least a portion of a side surface of the lower semiconductor chip 310.

The second bump structure 351 may be arranged to overlap the first bump pad 313. The second bump structure 351 may be arranged to be in contact with a first upper pad 124 that is arranged on the substrate 600. The second bump structure 351 may electrically connect the third chip structure 300 and the substrate 600 to each other. The lower semiconductor chip 310 may receive at least one of a control signal, a power signal, and/or a ground signal for an operation of the lower semiconductor chip 310 from the outside (e.g., an external or host device) through the second bump structure 351. In addition, the lower semiconductor chip 310 may receive a data signal that is to be stored in the lower semiconductor chip 310 from the outside, or may provide data that is stored in the lower semiconductor chip 310 to the outside. For example, the second bump structure 351 may include a pillar structure, a ball structure, or a solder layer.

The upper semiconductor chip 330 may include a second semiconductor substrate 334, a second device layer 331, and a third bump pad 333. Because the upper semiconductor chip 330 may have the same or similar characteristics as the lower semiconductor chip 310, differences from the lower semiconductor chip 310 are mainly described.

The second semiconductor substrate 334 may have an upper surface and a lower surface, which are opposite to each other. The lower surface of the second semiconductor substrate 334 may face the lower semiconductor chip 310, and the upper surface of the second semiconductor substrate 334 may be a surface opposite to the lower surface of the second semiconductor substrate 334. The upper surface may be referred to as an inactive surface, and the lower surface may be referred to as an active surface.

The second device layer 331 may include a second wire pattern 332 that is electrically connected to a plurality of semiconductor devices that are formed on the second semiconductor substrate 334. The second wire pattern 332 may include a metal wire layer and a via plug. For example, the second wire pattern 332 may have a multi-layered structure where two or more metal wire layers and/or two or more via plugs are alternately stacked.

According to some embodiments of the present inventive concept, the second device layer 331 may be formed on a lower surface of the second semiconductor substrate 334, which is an active surface. For example, the second device layer 331 may be formed between the first semiconductor substrate 314 and the second semiconductor substrate 334. The second device layer 331 may be positioned below the second semiconductor substrate 334. The second semiconductor substrate 334 may be spaced apart from the lower semiconductor chip 310 in the vertical direction Z with the second device layer 331 therebetween.

The third bump pad 333 may be arranged on the lower surface of the second device layer 331 and may be electrically connected to the second wire pattern 332 that is disposed inside the second device layer 331.

The first bump 371 may be disposed between the lower semiconductor chip 310 and the upper semiconductor chip 330. The first bump 371 may electrically connect the lower semiconductor chip 310 and the upper semiconductor chip 330 to each other. A test bump 373 may be formed adjacent to the first bump 371. The first bump 371 and the test bump 373 are described in detail below with reference to FIG. 2 and subsequent drawings. As described below, the first bump 371 may correspond to the first bump 1300 of FIG. 2, and the test bump 373 may correspond to the test bump 1200 of FIG. 2. This may indicate that the first bump 371 and the test bump 373 of the semiconductor package 12 of FIG. 1C are included, since an embodiment of the present inventive concept includes the first bump 1300 and the test bump 1200 of FIG. 2. The semiconductor package 12 of FIG. 1C may include, for example, a three-dimensional (3D) integrated circuit (IC) package.

The first bump 371 may be arranged to be in contact with the second bump pad 316 and the third bump pad 333. The first bump 371 may electrically connect the lower semiconductor chip 310 and the upper semiconductor chip 330 to each other. The upper semiconductor chip 330 may be electrically connected to the lower semiconductor chip 310 through the first bump 371 that is disposed between the lower semiconductor chip 310 and the upper semiconductor chip 330. The upper semiconductor chip 330 may receive at least one of a control signal, a power signal, and/or a ground signal for an operation of the upper semiconductor chip 330 through the first bump 371. In addition, the upper semiconductor chip 330 may receive a data signal that is to be stored in the upper semiconductor chip 330, or may provide data that is stored in the upper semiconductor chip 330 to the outside.

The underfill material layer 372 may be disposed between the upper surface of the lower semiconductor chip 310 and the lower surface of the upper semiconductor chip 330. Because the underfill material layer 372 is substantially the same as or similar to the underfill material layer described with reference to FIGS. 1A and 1B, a detailed description thereof is omitted.

FIG. 2 is a schematic diagram illustrating portions AA to CC respectively shown in FIGS. 1A to 1C. FIG. 2 may be understood as an enlarged view of portions AA, BB, and CC in the semiconductor packages 10, 11, and 12 of FIGS. 1A to 1C, but is a diagram in which left and right sides are symmetrical compared to portions AA, BB, and CC for convenience.

A semiconductor chip 1000 of FIG. 2 may correspond to the second chip structure 400 of FIG. 1A, the semiconductor chip 210 of FIG. 1B, and the upper semiconductor chip 330 of FIG. 1C. A lower silicon 2000 may correspond to the first substrate 100 of FIG. 1A, the semiconductor chip 210 of FIG. 1B, and the lower semiconductor chip 310 of FIG. 1C. As described above, the first bump 1300 and the test bump 1200 of FIG. 2 may correspond to the first bumps and test bumps of FIGS. 1A to 1C, respectively.

Referring to FIG. 2, a semiconductor package 20 may include the semiconductor chip 1000, a bump pad 1050, a passivation layer 1100, the first bump 1300, the test bump 1200, an underfill material layer 1500, and the lower silicon 2000. As described above, the semiconductor chip 1000 corresponds to the second chip structure 400 of FIG. 1A, the semiconductor chip 210 of FIG. 1B, and the upper semiconductor chip 330 of FIG. 1C, and the lower silicon 200 corresponds to the first substrate 100 of FIG. 1A, the semiconductor chip 210 of FIG. 1B, and the lower semiconductor chip 310 of FIG. 1C, and thus redundant descriptions thereof may be omitted or briefly discussed.

The semiconductor chip 1000 may include an active layer 1010 and a semiconductor substrate 1030. The active layer 1010 may include an upper surface, which faces the semiconductor substrate 1030, and a lower surface that is opposite to the upper surface thereof.

The bump pad 1050 may be formed on the lower surface of the active layer 1010. The bump pad 1050 may be formed to cover a portion of the lower surface of the active layer 1010. According to some embodiments of the present inventive concept, the bump pad 1050 may include, for example, aluminum, gold indium, or tin.

The bump pad 1050 may include a first surface, which is in contact with the active layer 1010, and a second surface that is opposite to the first surface. The passivation layer 1100 may be formed on the second surface of the bump pad 1050.

The passivation layer 1100 may cover the bump pad 1050. According to embodiments of the present inventive concept, the passivation layer 1100 may cover only a portion of the second surface of the bump pad 1050. For example, the passivation layer 1100 may include a first opening 1110 exposing a portion of the second surface of the bump pad 1050, and a second opening 1130 exposing another portion of the second surface of the bump pad 1050. Accordingly, the bump pad 1050 may be exposed by the passivation layer 1100 through the first opening 1110 and the second opening 1130.

According to some embodiments of the present inventive concept, a cross sectional area of the second opening 1130 along a X-Y plane may be greater than that of the first opening 1110 along the X-Y plane.

The first bump 1300 may be formed on the second surface of the bump pad 1050. According to some embodiments of the present inventive concept, the first bump 1300 may be physically connected to the bump pad 1050 through the first opening 1110 of the passivation layer 1100. The first bump 1300 may be configured to electrically connect the semiconductor chip 1000 and the lower silicon 2000 to each other.

The first bump 1300 may include a metal layer 1320 and a solder 1310. The metal layer 1320 may be formed through a seed metal layer 1400 that is formed on the bump pad 1050 and in the first opening 1110 of the passivation layer 1100, and the solder 1310 may be formed on the metal layer 1320. The metal layer 1320 may include, for example, copper, nickel, or the like. The solder 1310 may be electrically connected to a pad 2010 that is formed on the lower silicon 2000.

According to some embodiments of the present inventive concept, the seed metal layer 1400 may fill the first opening 1110, and the portion of the second surface of the bump pad 1050, which is exposed through the first opening 1110, may be covered by the seed metal layer 1400. For example, the seed metal layer 1400 may completely fill the first opening 1110, and the portion of the second surface of the bump pad 1050, which is exposed through the first opening 1110, may be entirely covered by the seed metal layer 1400.

According to some embodiments of the present inventive concept, the first bump 1300 may include a micro bump.

The test bump 1200 may be formed on the second surface of the bump pad 1050. According to some embodiments of the present inventive concept, the test bump 1200 may be formed on the second surface of the bump pad 1050, which is exposed through the second opening 1130 of the passivation layer 1100. In some embodiments of the present inventive concept, the test bump 1200 may be formed on at least a portion of the second surface of the bump pad 1050, which is exposed through the second opening 1130. For example, among the second surface of the bump pad 1050, which is exposed through the second opening 1130, there may be regions not covered by the test bump 1200.

The test bump 1200 may include a test metal layer 1220 and a solder 1210. The test metal layer 1220 may include, for example, copper, nickel, or the like. The test metal layer 1220 may be formed through the seed metal layer 1400 that is formed on a portion of the second surface of the bump pad 1050, which is exposed through the second opening 1130 of the passivation layer 1100. The solder 1210 may be formed on the test metal layer 1220.

The test metal layer 1220 may include at least one of nickel and/or copper. According to some embodiments of the present inventive concept, the test metal layer 1220 may include the same component as the metal layer 1320 of the first bump 1300. For example, when the metal layer 1320 of the first bump 1300 includes copper, the test metal layer 1220 may include copper. In addition, when the metal layer 1320 of the first bump 1300 includes nickel, the test metal layer 1220 may include nickel.

In addition, the test metal layer 1220 may include a different material from the metal layer 1320 of the first bump 1300. For example, when the metal layer 1320 of the first bump 1300 includes copper, the test metal layer 1220 may include nickel.

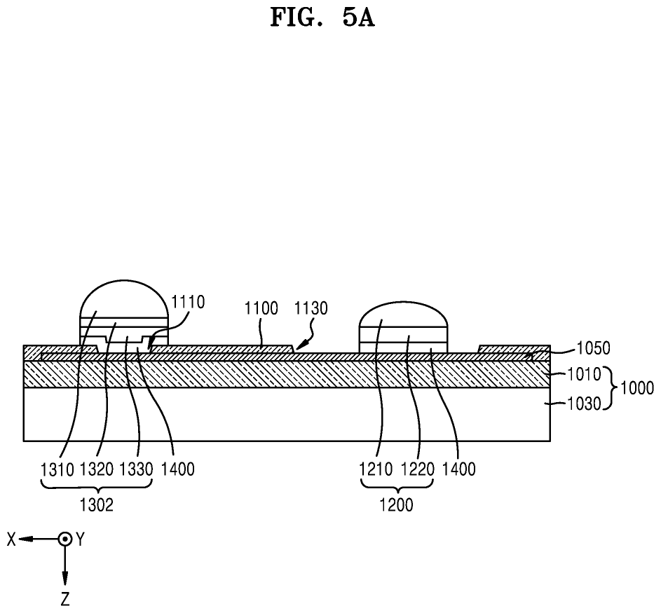

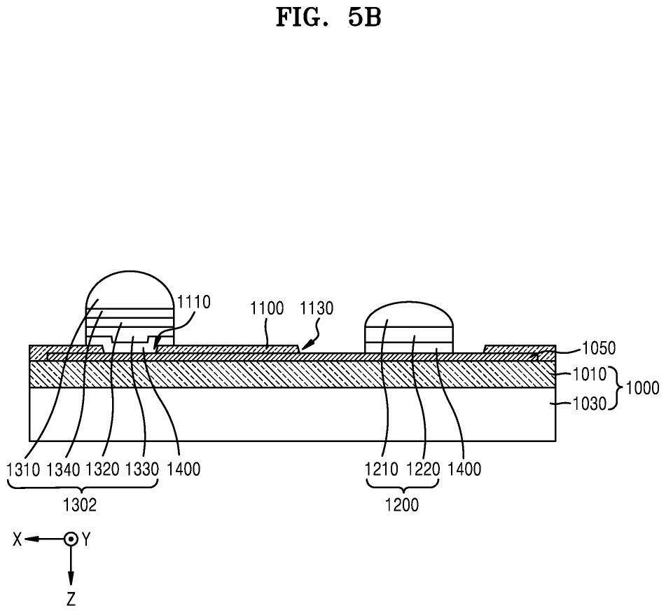

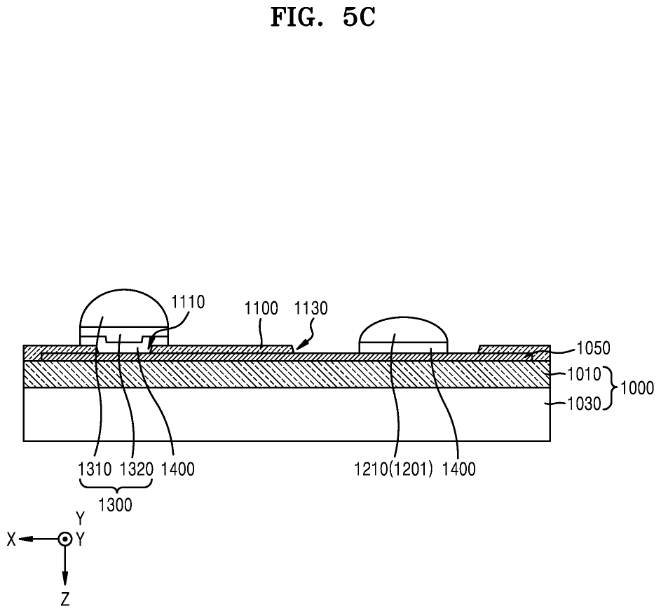

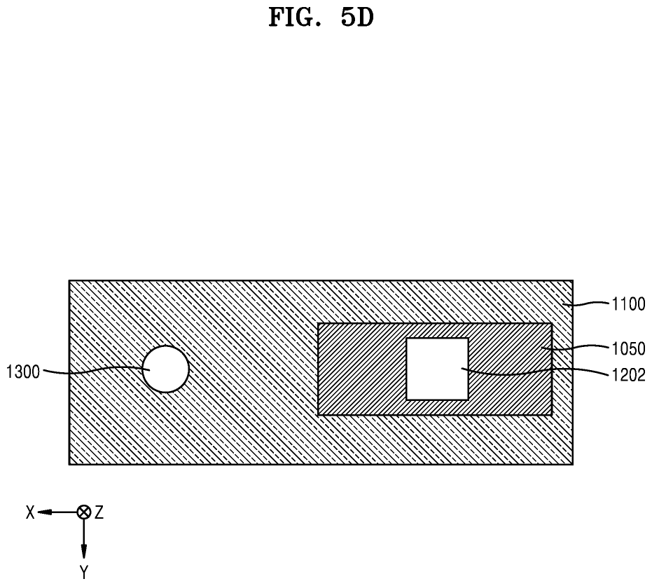

The metal layer 1320 of the first bump 1300 may include at least one layer. In addition, the metal layer 1320 of the first bump 1300 may include more layers than the test metal layer 1220. For example, the metal layer 1320 of the first bump 1300 may include various multi-layers compared to the test metal layer 1220. The multi-layer may be understood as a shape in which one layer including copper and one layer including nickel are alternately stacked on each other. The multi-layer is described in detail below with reference to FIGS. 5A to 5B.

The test bump 1200 may have greater ductility than that of the bump pad 1050. For example, curvatures may be formed on the surfaces of the first bump 1300 and the test bump 1200. For example, the first bump 1300 and the test bump 1200 may have round surfaces through a reflow process. In other words, surfaces of the first bump 1300 and the test bump 1200 may be curved. For example, the first bump 1300 may have a different radius of curvature than that of the test bump 1200.

The test bump 1200 may be in contact with a probe tip during an electrical die sorting (EDS) test. For example, in the EDS test, the probe tip may inspect whether the semiconductor chip 1000 is defective through contact with the test bump 1200.

When an EDS test is performed on a semiconductor package including a micro bump, in a case where an inspection is performed by allowing a probe tip to be into contact with the second surface of the bump pad 1050, which is exposed through the second opening 1130, the contact between the probe tip and the bump pad 1050 may cause damage to the surface of the bump pad 1050 and degrade a test result.

However, in the semiconductor package 20 according to an embodiment of the present inventive concept, an EDS test is performed by allowing a probe tip to be in contact with the test bump 1200, and thus, damage applied to the test bump 1200 may be reduced due to characteristics of the test bump 1200 having superior ductility compared to that of the bump pad 1050, and reliability of the EDS test may also be increased. In addition, the probe tip may be easily put in contact with the test bump 1200 and a degree of integration of the semiconductor package 20 may be increased by optimizing the shape and number of the test bump 1200.

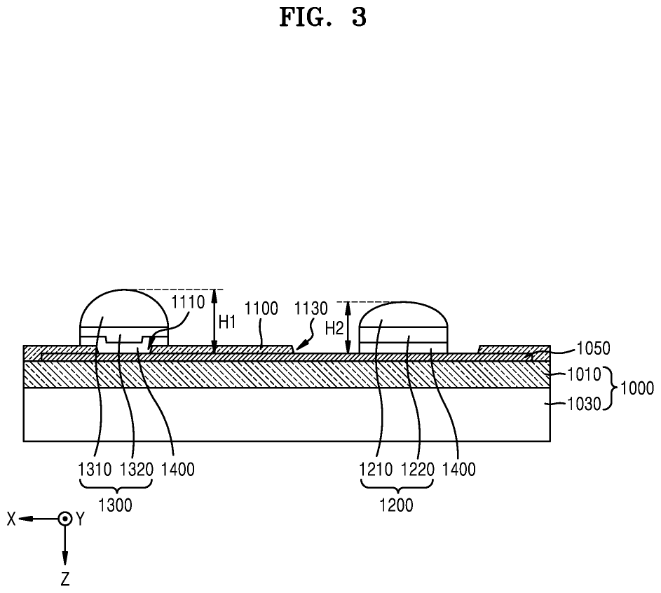

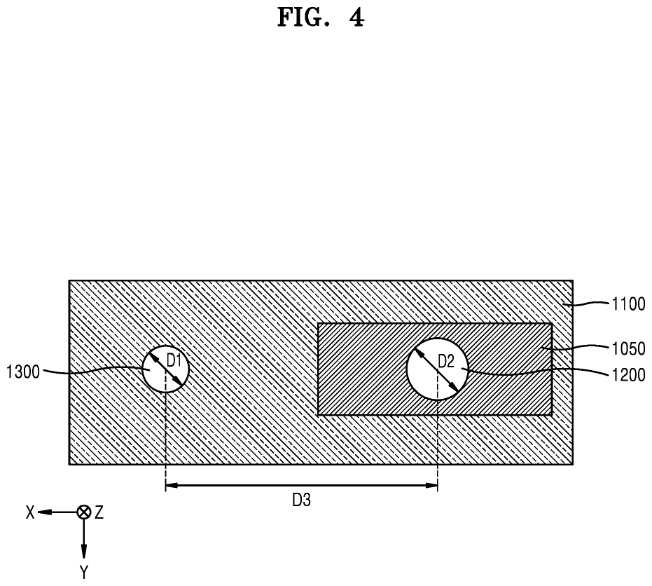

FIG. 3 is a cross-sectional view illustrating the first bump 1300 and the test bump 1200 of FIG. 2. FIG. 4 is a plan view illustrating the first bump 1300 and the test bump 1200 of FIG. 2. For convenience, FIG. 3 is a diagram obtained by rotating FIG. 2 180 degrees and in which some components are omitted for convenience of description and understanding, and FIG. 4 is a plan view obtained by viewing FIG. 3 in the vertical direction Z. In other words, FIG. 4 is a plan view of FIG. 3.

Referring to FIGS. 3 and 4, the bump pad 1050 may be formed on the active layer 1010 of the semiconductor chip 1000. In addition, the passivation layer 1100 may cover the bump pad 1050, and the first bump 1300 may be in contact with the bump pad 1050 through the first opening 1110 that is formed in the passivation layer 1100. The test bump 1200 may be in contact with the bump pad 1050 through the second opening 1130 that is formed in the passivation layer 1100.

According to some embodiments of the present inventive concept, a length H1 of the first bump 1300 in the vertical direction Z may range from about 5 μm to about 50 μm. A horizontal cross section of the first bump 1300 may have a diameter ranging from about 5 μm to about 30 μm.

According to some embodiments of the present inventive concept, a maximum length D1 of the first bump 1300 in a horizontal direction may range from about 5 μm to about 30 μm. The maximum length in the horizontal direction may be understood as, for example, a diameter of the first bump 1300 when a horizontal cross section of the first bump 1300 has a circle shape, and when the horizontal cross section of the first bump 1300 is a polygon, the maximum length in the horizontal direction may be understood as a length between two points of the polygon that are farthest from each other.

The test bump 1200 may have a greater horizontal cross sectional area than that of the first bump 1300. For example, when a horizontal cross section of the test bump 1200 is circular, a maximum length D2 of the test bump 1200 in the horizontal direction may be greater than the maximum length D1 of the first bump 1300 in the horizontal direction by about 5 μm or more. For example, the maximum length D2 of the test bump 1200 may have a value greater than that of the maximum length D1 of the first bump 1300 by about 5 μm to about 15 μm.

When the test bump 1200 has a greater horizontal cross sectional area than that of the first bump 1300, a probe tip may easily contact the test bump 1200 in an EDS test to perform the test.

The test bump 1200 may have a vertical length H2 less than a vertical length H1 of the first bump 1300. In a case where the vertical length H2 of the test bump 1200 is less than the vertical length H1 of the first bump 1300, when the semiconductor chip 1000 and the lower silicon 2000 are physically and electrically connected to each other by the first bump 1300, the test bump 1200 might not affect the connection.

A horizontal distance D3 between a center of the test bump 1200 and a center of the first bump 1300 may range from about 20 μm to about 50 μm. When the range of the horizontal distance D3 is in a range of about 20 μm to about 50 μm, the test bump 1200 may easily contact a probe tip, and a space occupied by the test bump 1200 in the semiconductor package 20 may be minimized.

According to some embodiments of the present inventive concept, the vertical length H2 of the test bump 1200 may be less than the vertical length H1 of the first bump 1300 by about 5 μm or more. For example, a difference between the vertical length H2 of the test bump 1200 and the vertical length H1 of the first bump 1300 may range from about 5 μm to about 15 μm.

When the test bump 1200 has a value within the above ranges, that is, a horizontal cross sectional area, vertical length H2, and the horizontal distance D3 between a center of the test bump 1200 and a center of the first bump 1300, during an EDS test, a probe tip may easily contact the test bump 1200, and a space occupied by the test bump 1200 in the semiconductor package may be minimized. For example, when the test bump 1200 has a numerical value within the above range, the size of the semiconductor package may be minimized while increasing the reliability of the EDS test.

FIG. 5A is a cross sectional of a semiconductor package according to an embodiment of the present inventive concept. Hereinafter, contents overlapping those given with reference to FIGS. 1A to 4 may be omitted or briefly discussed.

Referring to FIG. 5A, a first bump 1301 may include a plurality of metal layers 1320 and 1330. For example, the first bump 1301 may include a metal layer 1330, which includes nickel, and a metal layer 1320, which is stacked on the metal layer 1330 and includes copper. When the first bump 1301 includes the plurality of metal layers 1320 and 1330, deformation of the first bump 1301 by an external environment may be prevented, and reliability of the first bump 1301 may be increased. According to some embodiments of the present inventive concept, the first bump 1301 may include three or more metal layers, and in this case, components included in respective metal layers may be different from each other.

According to some embodiments of the present inventive concept, the test bump 1200 may include the test metal layer 1220. The test metal layer 1220 may include copper and/or nickel. In this case, the number of metal layers of the first bump 1301 may be greater than that of the test metal layers 1220. For example, the first bump 1301 may include one metal layer 1330, which includes nickel, and another metal layer 1320, which is stacked on the metal layer 1330 and includes copper, and the test bump 1200 may include only one test metal layer 1220.

FIG. 5B is a cross-sectional view of a semiconductor package according to an embodiment of the present inventive concept. Hereinafter, contents overlapping those given with reference to FIGS. 1A to 5A may be omitted or briefly discussed.

Referring to FIG. 5B, a first bump 1302 may include a plurality of metal layers 1320, 1330, and 1340. For example, the first bump 1302 is formed on the seed metal layer 1400. In addition, the metal layer 1330 may be formed on the seed metal layer 1400, and another metal layer 1320 may be formed on the metal layer 1330. Another metal layer 1340 may be formed on the metal layer 1320. For example, the first bump 1302 may include three metal layers 1320, 1330, and 1340. In addition, the test bump 1200 may include a smaller number of test metal layers 1220 than that of the first bump 1302. For example, the test bump 1200 may include less layers than that of the first bump 1302.

According to some embodiments of the present inventive concept, the metal layers 1320, 1330, and 1340 may include at least one of copper and/or nickel. For example, the metal layer 1330, which is positioned at a lowermost portion, may include copper, and the metal layer 1320 stacked thereon may include nickel. In addition, the metal layer 1340, which is positioned at an uppermost portion, may include copper. As a result, the first bump 1302 may include various multi-layered metal layers compared to the test bump 1200.

As the number of metal layers 1320, 1330, and 1340 increases, the first bump 1302 is prevented from being deformed by an external environment, and operation reliability of the first bump 1302 may be increased.

FIG. 5C is a cross-sectional view of a semiconductor package according to an embodiment of the present inventive concept. Hereinafter, contents overlapping those given with reference to FIGS. 1A to 5B may be omitted or briefly discussed.

Referring to FIG. 5C, a test bump 1201 might not include a test metal layer. For example, the test bump 1201 includes the solder 1210, and the solder 1210 may be directly formed on the seed metal layer 1400. In the first bump 1300, the metal layer 1320 may be formed on the seed metal layer 1400, and the solder 1310 may be formed on the metal layer 1320. In addition, as an example, in the test bump 1201, the solder 1210 may be directly formed on the seed metal layer 1400. As a result, as the test bump 1201 does not include a test metal layer, a length (or, e.g., height) of the test bump 1201 in the vertical direction Z may be reduced, and a degree of integration of the semiconductor package may be increased. In addition, as the test bump 1201 does not include a test metal layer, a semiconductor package may be formed such that a length of the first bump 1300 in the vertical direction Z is greater than a length of the test bump 1201 in the vertical direction Z. In addition, as a process of forming a test metal layer may be excluded from an operation of manufacturing a semiconductor package, the operation may be further simplified.

FIG. 5D is a cross-sectional view of a semiconductor package according to an embodiment of the present inventive concept.

Referring to FIG. 5D, a test bump 1202 may have a polygonal shape with a cross section along an X-Y plane. According to some embodiments of the present inventive concept, as shown in FIG. 5D, the test bump 1202 may have a quadrangular cross section along the X-Y plane (e.g., from a plan view).

When the cross section of the test bump 1202 along the X-Y plane has a polygonal shape, an area where a probe tip may contact the test bump 1202 during an EDS test may increase, so reliability of the EDS test may be increased.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a semiconductor chip comprising an active layer;
a bump pad positioned on the active layer and comprising a first surface and a second surface, wherein the first surface is disposed on the active layer, and the second surface is opposite to the first surface;
a passivation layer covering the bump pad and comprising a first opening and a second opening, wherein the first opening exposes a first portion of the second surface of the bump pad, and the second opening exposes a second portion of the second surface of the bump pad;
a first bump disposed on the first portion of the second surface of the bump pad, which is exposed through the first opening; and
a test bump disposed on the second portion of the second surface of the bump pad, which is exposed through the second opening,
wherein the first bump comprises at least one metal layer, and
a length of the test bump in a vertical direction is less than a length of the first bump in the vertical direction.

2. The semiconductor package of claim 1, wherein a length of the first bump in a first horizontal direction is in a range of about 5 μm to about 30 μm.

3. The semiconductor package of claim 1, wherein a difference between a length of the test bump in the vertical direction and a length of the first bump in the vertical direction is in a range of about 5 μm to about 15 μm.

4. The semiconductor package of claim 1, wherein a cross-sectional area of the test bump in a horizontal direction is greater than a cross-sectional area of the first bump in the horizontal direction.

5. The semiconductor package of claim 1, wherein the at least one metal layer of the first bump comprises at least one of nickel or copper.

6. The semiconductor package of claim 5, wherein the test bump comprises a test metal layer, and
a number of metal layers of the first bump is greater than a number of the test metal layers.

7. The semiconductor package of claim 5, wherein each of a surface of the first bump and a surface of the test bump is curved.

8. The semiconductor package of claim 1, wherein the test bump has a polygonal shape when viewed from the vertical direction.

9. The semiconductor package of claim 1, wherein the first bump is electrically connected to an interposer substrate.

10. The semiconductor package of claim 1, wherein the first bump is electrically connected to a lower semiconductor chip, wherein the lower semiconductor chip comprises a through electrode therein.

11. The semiconductor package of claim 1, wherein a distance from a center of the first bump to a center of the test bump in a horizontal direction is in a range of about 20 μm to about 50 μm.

12. A semiconductor package comprising:
a semiconductor chip comprising an active layer;
a bump pad positioned on the active layer and comprising a first surface and a second surface, wherein the first surface is disposed on the active layer, and the second surface is opposite to the first surface;
a passivation layer covering the bump pad and comprising a first opening and a second opening, wherein the first opening exposes a first portion of the second surface of the bump pad, and the second opening exposes a second portion of the second surface of the bump pad;
a first bump disposed on the first portion of the second surface of the bump pad, which is exposed through the first opening;
a test bump disposed on the second portion of the second surface of the bump pad, which is exposed through the second opening;
an underfill material layer at least partially surrounding the first bump and the test bump; and
lower silicon on which a pad, which is electrically connected to the first bump, is formed,
wherein a length of the first bump in a first horizontal direction is in a range of about 5 μm to about 30 μm, wherein a length of the first bump in a vertical direction is in a range of about 5 μm to about 50 μm,
wherein the first bump comprises at least one metal layer, and a length of the test bump in the vertical direction is less than a length of the first bump in the vertical direction.

13. The semiconductor package of claim 12, wherein a cross-sectional area of the test bump in a horizontal direction is greater than a cross-sectional area of the first bump in the horizontal direction.

14. The semiconductor package of claim 12, wherein a horizontal cross-sectional area of the second opening is greater than a horizontal cross-sectional area of the test bump.

15. The semiconductor package of claim 12, wherein the test bump comprises a test metal layer and a solder,
a number of the at least one metal layer of the first bump is greater than a number of the test metal layers, and
the at least one metal layer comprises at least one of copper or nickel.

16. The semiconductor package of claim 12, wherein each of a surface of the first bump and a surface of the test bump is curved.

17. The semiconductor package of claim 12, wherein the test bump has a polygonal shape when viewed from the vertical direction.

18. A semiconductor package comprising:
a semiconductor chip comprising an active layer;
a bump pad positioned on the active layer and comprising a first surface and a second surface, wherein the first surface is in contact with the active layer, and the second surface is opposite to the first surface;
a passivation layer disposed on the bump pad and comprising a first opening and a second opening, wherein the first opening exposes a first portion of the second surface of the bump pad, and the second opening exposes a second portion of the second surface of the bump pad;
a first bump disposed on the first portion of the second surface of the bump pad, which is exposed through the first opening, wherein the first bump comprises a metal layer and a solder, wherein the metal layer comprises at least one layer;
a test bump disposed on the second portion of the second surface of the bump pad, which is exposed through the second opening, wherein the test bump comprises a test metal layer and a solder;
an underfill material layer at least partially surrounding the first bump and the test bump;
a seed metal layer formed in each of the first opening and the second opening; and
lower silicon on which a pad, which is electrically connected to the first bump, is formed,
wherein each of a surface of the first bump and a surface of the test bump is curved,
wherein a length of the first bump in a first horizontal direction is in a range of about 5 μm to about 30 μm, and a length of the first bump in a vertical direction is in a range of about 5 μm to about 50 μm,
wherein a length of the test bump in a vertical direction is less than a length of the first bump in the vertical direction,
wherein the metal layer of the first bump comprises at least one of copper or nickel, and
wherein a cross-sectional area of the test bump in a horizontal direction is greater than a cross-sectional area of the first bump in the horizontal direction.

19. The semiconductor package of claim 18, wherein the lower silicon comprises an interposer substrate, and
the first bump is electrically connected to the interposer substrate.

20. The semiconductor package of claim 18, wherein the lower silicon comprises a lower semiconductor chip, wherein the lower semiconductor chip comprises a through electrode therein, and
the first bump is electrically connected to the lower semiconductor chip.
